(19) United States
(12) Patent Application Publication
(10) Pub. No.: US 2024/0186411 A1
(43) Pub. Date: Jun. 6, 2024

(54) SEMICONDUCTOR STRUCTURE AND MANUFACTURING METHOD THEREOF

(71) Applicant: Advanced Power Electronics Corp., Hsinchu County (TW)

(72) Inventor: Yen-Yuan HUANG, Hsinchu County (TW)

(21) Appl. No.: 18/485,321

(22) Filed: Oct. 12, 2023

(30) Foreign Application Priority Data
Dec. 1, 2022 (TW) 111146244

(51) Int. Cl. H01L 29/78; H01L 29/40; H01L 29/417; H01L 29/423; H01L 29/66

(52) U.S. Cl. CPC H01L 29/7827; H01L 29/401; H01L 29/41741; H01L 29/4236; H01L 29/66484; H01L 29/66666; H01L 29/7831

(57) ABSTRACT

A semiconductor structure includes a first insulating layer, a source region, a second insulating layer, and two gate regions. The first insulating layer is disposed in a trench of a semiconductor substrate. The source region is disposed in the first insulating layer. The source region has a first portion and a second portion extending from the first portion. The first insulating layer surrounds the first portion of the source region. The second insulating layer is disposed on the first insulating layer and extends to a top surface of the semiconductor substrate. The second insulating layer covers the second portion of the source region. The two gate regions are disposed in the second insulating layer. The two gate regions are separated by the second insulating layer.

### CROSS-REFERENCE TO RELATED APPLICATION

This application claims priority to Taiwan Application Serial Number 111146244, filed Dec. 1, 2022, which is herein incorporated by reference.

### BACKGROUND

### Technical Field

The present disclosure relates to a semiconductor structure and a manufacturing method of a semiconductor structure.

### Description of Related Art

Generally speaking, a shielded gate trench type metal-oxide-semiconductor field effect transistor (SGT-MOSFET) has a low on-resistance. Therefore, it has the advantage of significantly reducing power consumption and is widely used in high-frequency and low-voltage power devices. However, since a SGT-MOSFET has a trench structure, the filling of electrode materials is susceptible to the shape of the trench structure or the type of electrode materials. In turn, the trench structure affects the device reliability of the SGT-MOSFET and the electrical characteristics of the electrodes.

Accordingly, how to provide a semiconductor structure and a manufacturing method of a semiconductor structure to solve the aforementioned problems becomes an important issue to be solved by those in the industry.

### SUMMARY

An aspect of the disclosure is to provide a semiconductor structure and a manufacturing method of a semiconductor structure that may efficiently solve the aforementioned problems.

According to an embodiment of the disclosure, a semiconductor structure includes a first insulating layer, a source region, a second insulating layer, and two gate regions. The first insulating layer is disposed in a trench of a semiconductor substrate. The source region is disposed in the first insulating layer. The source region has a first portion and a second portion extending from the first portion. The first insulating layer surrounds the first portion of the source region. The second insulating layer is disposed on the first insulating layer and extends to a top surface of the semiconductor substrate. The second insulating layer covers the second portion of the source region. The two gate regions are disposed in the second insulating layer. The two gate regions are separated by the second insulating layer.

In an embodiment of the disclosure, the two gate regions are disposed symmetrically along a longitudinal direction of the trench.

In an embodiment of the disclosure, a length of the first portion of the source region is greater than a length of one of the two gate regions.

In an embodiment of the disclosure, the semiconductor substrate has an implantation region. A position of the implantation region corresponds to a position of one of the two gate region electrodes.

In an embodiment of the disclosure, the semiconductor structure further includes a metal contact and a third insulating layer. The metal contact extends into the semiconductor substrate to contact the implantation region of the semiconductor substrate. The third insulating layer is disposed between the second insulating layer and the metal contact.

In an embodiment of the disclosure, the metal contact is in contact with the source region.

In an embodiment of the disclosure, the third insulating layer covers the two gate regions.

In an embodiment of the disclosure, the source region comprises polysilicon.

According to another embodiment of the disclosure, a manufacturing method of a semiconductor structure includes forming a first insulating layer in a trench of a semiconductor substrate. The manufacturing method further includes forming a source region in the first insulating layer. The source region has a first portion and a second portion extending from the first portion. The manufacturing method further includes etching the first insulating layer by wet etching to expose the second portion of the source region. The manufacturing method further includes forming a second insulating layer on the first insulating layer by wet oxidation. A part of the second portion of the source region is converted to the second insulating layer. The manufacturing method further includes forming two gate regions in the second insulating layer. The two gate regions are separated by the second insulating layer.

In an embodiment of the disclosure, the two gate regions are disposed symmetrically along a longitudinal direction of the trench.

In an embodiment of the disclosure, a length of the first portion of the source region is greater than a length of one of the two gate regions.

In an embodiment of the disclosure, polysilicon is used to form the source region in the first insulating layer.

In an embodiment of the disclosure, the manufacturing method further includes implanting a top surface of the semiconductor substrate such that the semiconductor substrate has an implantation region. A position of the implantation region corresponds to a position of one of the two gate regions.

In an embodiment of the disclosure, the manufacturing method further includes forming a third insulating layer on the second insulating layer. The third insulating layer covers the two gate regions. The manufacturing method further includes forming a metal contact on the third insulating layer. The metal contact extends into the semiconductor substrate to contact the implantation region of the semiconductor substrate.

In an embodiment of the disclosure, the metal contact is in contact with the source region.

Accordingly, in the semiconductor structure and the manufacturing method of the semiconductor structure of the present disclosure, by disposing the two gate regions of the semiconductor structure in the second insulating layer and separating the two gate regions by the second insulating layer, structural defects may be avoided when forming the gate regions. In addition, the two gate regions separated by the second insulating layer and disposed symmetrically can enhance the electrical characteristics of the semiconductor structure. Therefore, the device reliability of the gate regions of the semiconductor structure and the performance of the semiconductor structure may be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a partial cross-sectional view of a semiconductor structure at one view angle according to an embodiment of the disclosure;

FIG. 1B is a partial cross-sectional view of a semiconductor structure at another view angle according to an embodiment of the disclosure;

FIG. 2 is a flow chart of a manufacturing method of a semiconductor structure according to an embodiment of the disclosure;

FIG. 3, FIG. 4, FIG. 5, FIG. 6, FIG. 7, and FIG. 8 are partial cross-sectional views of different intermediate stages of a manufacturing method at one view angle according to an embodiment of the disclosure; and

FIG. 9 and FIG. 10 are partial cross-sectional views of different intermediate stages of a manufacturing method at another view angle according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

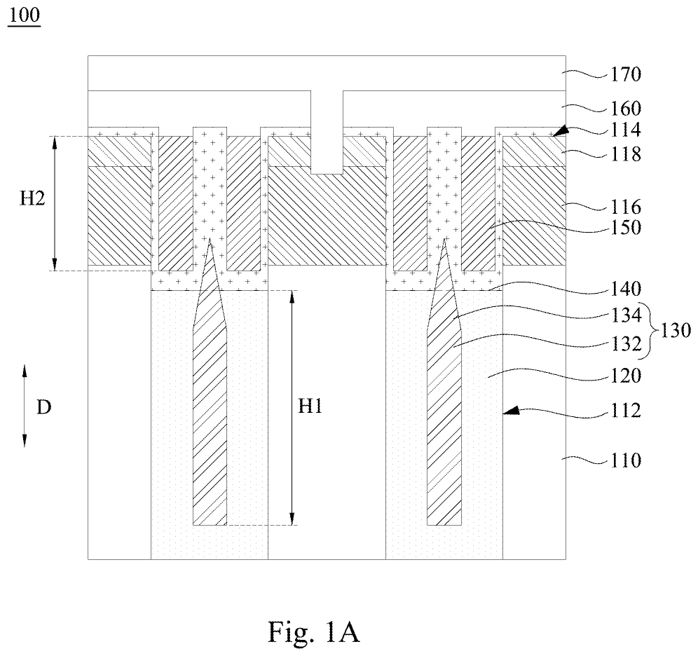

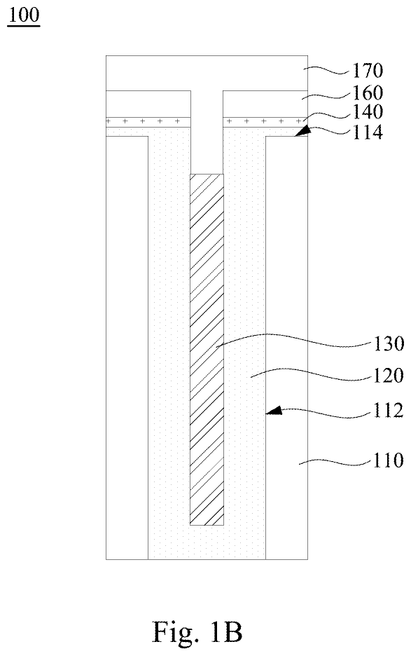

Reference is made to FIG. 1A. FIG. 1A illustrates a partial cross-sectional view of a semiconductor structure 100 at one view angle according to an embodiment of the present disclosure. For example, the semiconductor structure 100 may be applied to high-frequency and low-voltage power devices, such as shielded gate trench type metal oxide semi-field effect transistors (SGT-MOSFETs). The semiconductor structure 100 has a lower on-resistance. Therefore, it has the advantage of reducing power consumption. As shown in FIG. 1A, the semiconductor structure 100 includes a first insulating layer 120, a source region 130, a second insulating layer 140, and two gate regions 150. The first insulating layer 120 of the semiconductor structure 100 is disposed in a trench 112 of a semiconductor substrate 110. The source region 130 of the semiconductor structure 100 is disposed in the first insulating layer 120 of the semiconductor structure 100. The source region 130 of the semiconductor structure 100 has a first portion 132 and a second portion 134 extending from the first portion 132. In some embodiments, the material of the source region 130 of the semiconductor structure 100 may include polysilicon.

Furthermore, as shown in FIG. 1A, the first insulating layer 120 of the semiconductor structure 100 surrounds the first portion 132 of the source region 130. The second insulating layer 140 of the semiconductor structure 100 is disposed on the first insulating layer 120 and extends to a top surface 114 of the semiconductor substrate 110. In this embodiment, the second portion 134 of the source region 130 including polysilicon can be partially converted to the second insulating layer 140, for example, the second insulating layer 140 between the two gate regions 150, by wet oxidation. Additionally, the second insulating layer 140 may cover the remaining second portion 134 of the source region 130, as shown in FIG. 1A. The two gate regions 150 of the semiconductor structure 100 are disposed in the second insulating layer 140 of the semiconductor structure 100. It should be noted that the two gate regions 150 are separated by the second insulating layer 140, as shown in FIG. 1A. In detail, the two gate regions 150 are separated by the second insulating layer 140 to which the second portion 134 of the source region 130 is partially converted by wet oxidation.

To be more specific, the two gate regions 150 of the semiconductor structure 100 are disposed in the second insulating layer 140 and are separated by the second insulating layer 140. Such configuration may avoid structural defects when forming the gate regions 150. In addition, the two gate regions 150 separated by the second insulating layer 140 and disposed symmetrically can provide better electrical characteristics, thereby improving the device reliability of the gate regions 150 of the semiconductor structure 100 and the performance of the semiconductor structure 100.

In some embodiments, the two gate regions 150 of the semiconductor structure 100 may be disposed symmetrically along a longitudinal direction D of the trench 112 of the semiconductor substrate 110. For example, the longitudinal direction D of the trench 112 of the semiconductor substrate 110 may be a vertical direction. That is to say, the two gate regions 150 may be disposed symmetrically about the vertical direction, as shown in FIG. 1A. The two gate regions 150 are separated by the second insulating layer 140 to which the second portion 134 of the source region 130 is partially converted by wet oxidation. On top of that, in some embodiments, a length H1 of the first portion 132 of the source region 130 is greater than a length H2 of the two gate regions 150, as shown in FIG. 1A.

In some embodiments, the semiconductor substrate 110 of the semiconductor structure 100 has an implantation region. For example, the implantation region may include a P-type region 116 and an N-type region 118, as shown in FIG. 1A. In some embodiments, positions of the P-type region 116 and the N-type region 118 of the semiconductor substrate 110 correspond to positions of the two gate regions 150. In other words, the P-type region 116 and the N-type region 118 of the semiconductor substrate 110 are aligned with the two gate regions 150, as shown in FIG. 1A. Moreover, in some embodiments, the semiconductor structure 100 further includes a third insulating layer 160 and a metal contact 170. The third insulating layer 160 of the semiconductor structure 100 is disposed between the second insulating layer 140 and the metal contact 170. The metal contact 170 of the semiconductor structure 100 extends into the semiconductor substrate 110 to contact the implantation region of the semiconductor substrate 110 (i.e., the P-type region 116 and the N-type region 118).

Reference is made to FIG. 1B. FIG. 1B illustrates a partial cross-sectional view of a semiconductor structure 100 at another view angle according to an embodiment of the present disclosure. In detail, FIG. 1B illustrates a partial cross-sectional view of a contact at the source region 130 of the semiconductor structure 100. As shown in FIG. 1B, the first insulating layer 120 of the semiconductor structure 100 is disposed in the trench 112 of the semiconductor substrate 110. The source region 130 of the semiconductor structure 100 is disposed in the first insulating layer 120. In some embodiments, the material of the source region 130 may include polysilicon. The second insulating layer 140 of the semiconductor structure 100 is disposed on the first insulating layer 120. In some embodiments, the third insulating layer 160 of the semiconductor structure 100 is disposed between the second insulating layer 140 and the metal contact 170. The metal contact 170 extends into the semiconductor substrate 110 to contact the source region 130, as shown in FIG. 1B.

It should be understood that the connections between the components and the functions of the components that have been described will not be repeated. In the following paragraphs, a manufacturing method of a semiconductor structure will be described.

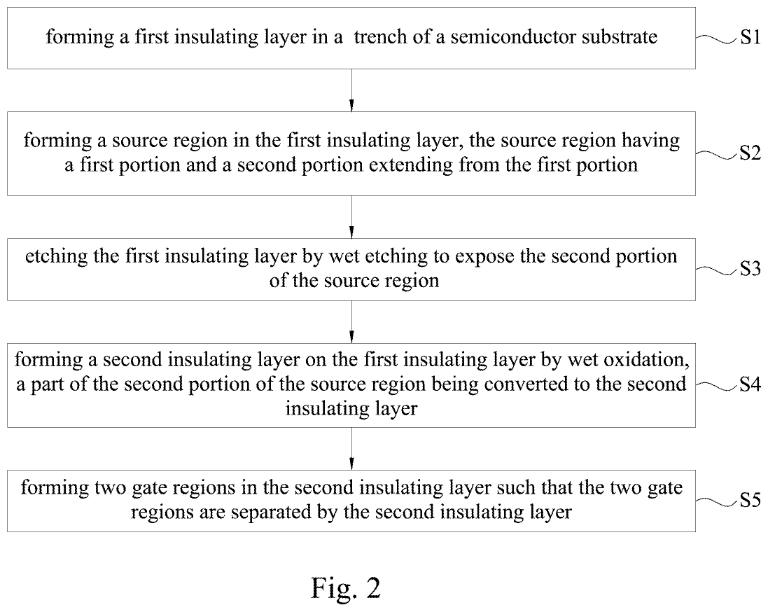

Reference is made to FIG. 2. FIG. 2 illustrates a flow chart of a manufacturing method of a semiconductor structure according to an embodiment of the present disclosure. As shown in FIG. 2, the manufacturing method includes the following steps. First, in the step S1, a first insulating layer is formed in a trench of a semiconductor substrate. Second, in the step S2, a source region is formed in the first insulating layer. After the step S2 is finished, the source region has a first portion and a second portion extending from the first portion. Then, in the step S3, the first insulating layer is etched by wet etching to expose the second portion of the source region. Later on, in the step S4, a second insulating layer is formed on the first insulating layer by wet oxidation. After the step S4 is conducted, the second portion of the source region is converted to the second insulating layer. In the end, in the step S5, two gate regions are formed in the second insulating layer. The two gate regions are separated by the second insulating layer. In the following paragraphs, each of the aforementioned steps will be explained in detail.

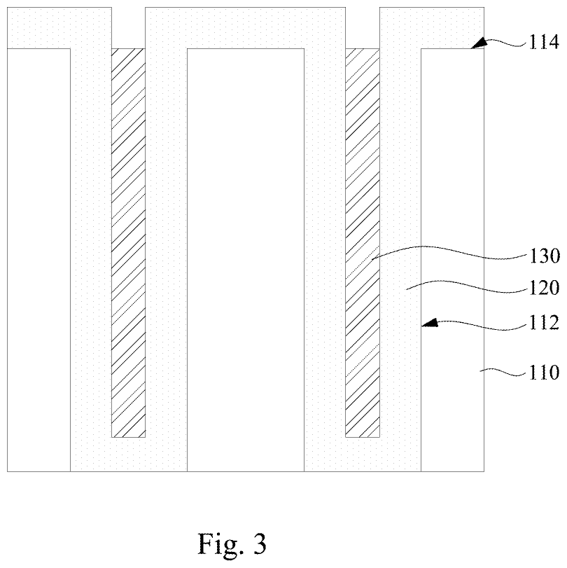

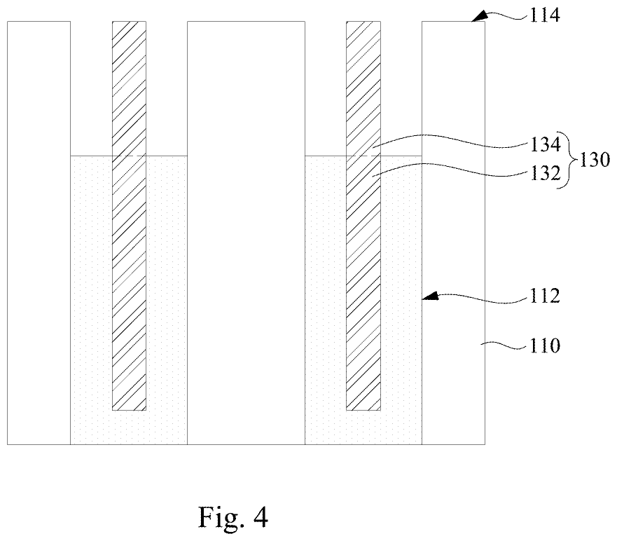

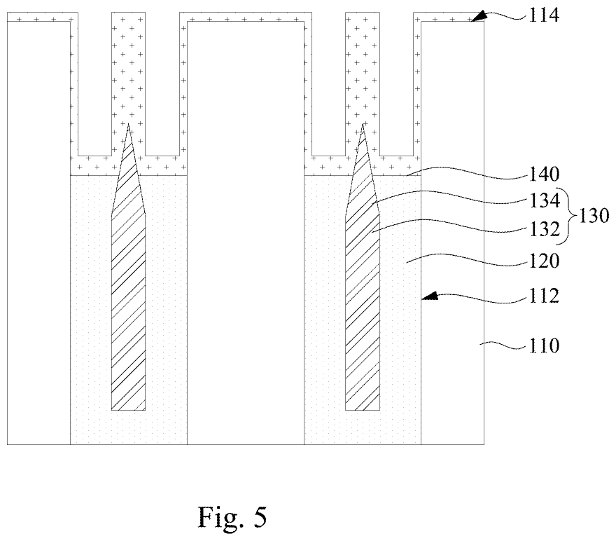

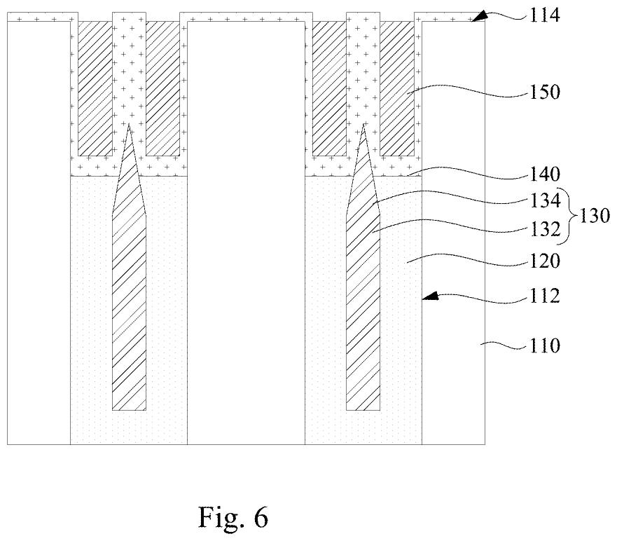

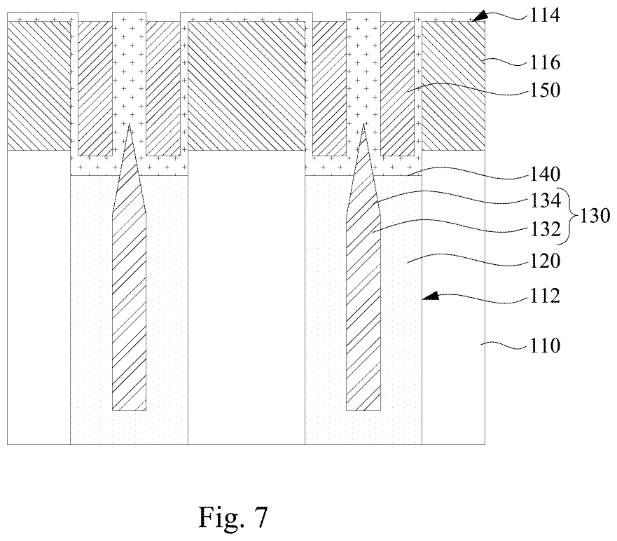

FIG. 3, FIG. 4, FIG. 5, FIG. 6, FIG. 7, and FIG. 8 illustrate partial cross-sectional views of different intermediate stages of the manufacturing method according to an embodiment of the present disclosure. Reference is made to FIG. 3. As shown in FIG. 3, a trench 112 may be first formed in a semiconductor substrate 110 by an etching process. Next, a first insulating layer 120 may be formed in the trench 112 and on a top surface 114 of the semiconductor substrate 110. For example, oxide may be used to form the first insulating layer 120. However, it is not limited thereto. After forming the first insulating layer 120, a source region 130 may be formed in the first insulating layer 120. In this embodiment, polysilicon is used to form the source region 130 in the first insulating layer 120.

Reference is made to FIG. 4 and FIG. 5. As shown in FIG. 4 and FIG. 5, after the source region 130 is formed in the first insulating layer 120, the first insulating layer 120 can be etched back by wet etching to expose the second portion 134 of the source region 130. After exposing the second portion 134 of the source region 130, the second insulating layer 140 may be formed on the first insulating layer 120 by wet oxidation. A part of the second portion 134 of the source region 130 is converted to the second insulating layer 140. In detail, in the wet oxidation process, the second portion 134 of the source region 130 including polysilicon can be partially converted to the second insulating layer 140. In addition, a ratio of a formation rate of the second insulating layer 140 on the second portion 134 of the source region 130 including polysilicon to a formation rate of the second insulating layer 140 on sidewalls of the trench 112 is about 3:1. In other words, the second insulating layer 140 forms faster on the second portion 134 of the source region 130 than on the sidewalls of the trench 112, which forms the structure shown in FIG. 5.

Reference is made to FIG. 6. As shown in FIG. 6, after forming the second insulating layer 140, two gate regions 150 can be formed in the second insulating layer 140. The two gate regions 150 are separated by the second insulating layer 140, as shown in FIG. 6. This configuration helps avoid structural defects occurred during the formation of the two gate regions 150. Such gate regions 150 can enhance electrical characteristics. In some embodiments, polysilicon may be used to form the two gate regions 150 in the second insulating layer 140.

Reference is made to FIG. 7 and FIG. 8. As shown in FIG. 7 and FIG. 8, after the gate regions 150 are formed in the second insulating layer 140, the top surface 114 of the semiconductor substrate 110 can be implanted such that the semiconductor substrate 110 has an implantation region. For example, in some embodiments, the implantation region may include a P-type region 116 and an N-type region 118. In some embodiments, positions of the P-type region 116 and the N-type region 118 of the semiconductor substrate 110 correspond to positions of the two gate regions 150.

Referring back to FIG. 1A, after the semiconductor substrate 110 is implanted, a third insulating layer 160 may be formed on the second insulating layer 140. The third insulating layer 160 covers the two gate regions 150. Next, after the third insulating layer 160 is formed, a metal contact 170 may be formed on the third insulating layer 160. The metal contact 170 extends into the semiconductor substrate 110 to contact the implantation region of the semiconductor substrate 110 (i.e., the P-type region 116 and N-type region 118). In addition, two gate regions 150 are formed in the second insulating layer 140. The two gate regions 150 are disposed along the longitudinal direction D of the trench 112 of the semiconductor substrate 110, as shown in FIG. 1A.

In this embodiment, the second portion 134 of the source region 130 including polysilicon can be partially converted to the second insulating layer 140, such as the second insulating layer 140 disposed between the two gate regions 150, by wet oxidation. The second insulating layer 140 may cover the remaining second portion 134 of the source region 130. The two gate regions 150 of the semiconductor structure 100 are disposed in the second insulating layer 140. In addition, the symmetrical configuration of the two gate regions 150 of the semiconductor structure 100 can help avoid structural defects when forming the gate regions 150. Furthermore, the two gate regions 150 separated by the second insulating layer 140 and disposed symmetrically can provide better electrical characteristics and improve the device reliability of the gate regions 150 of the semiconductor structure 100 and the performance of the semiconductor structure 100.

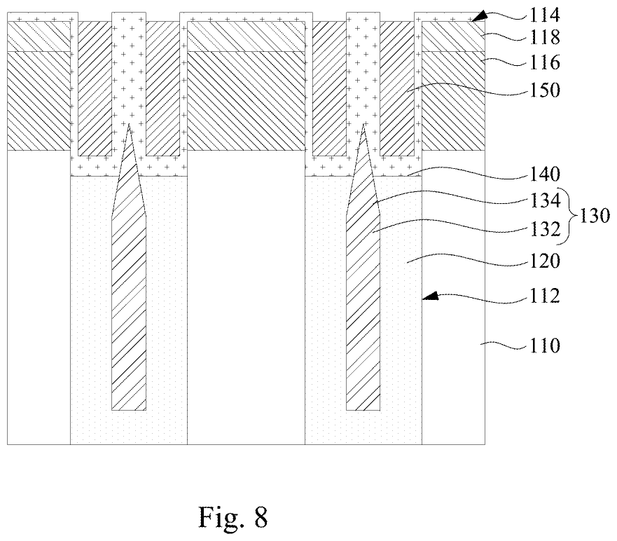

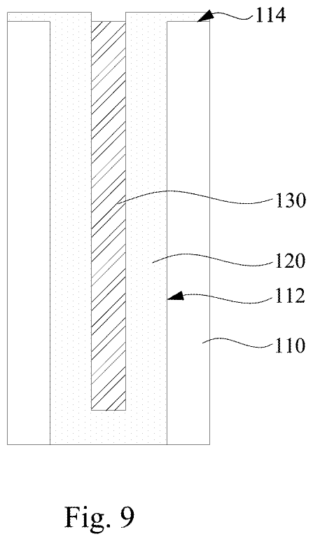

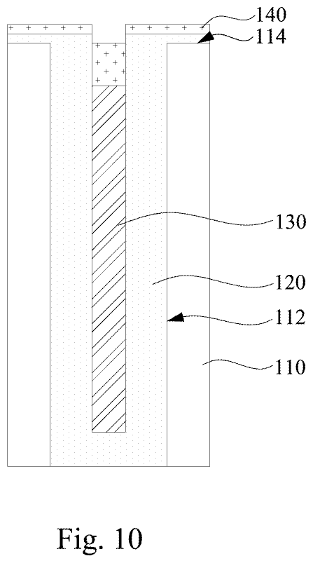

Reference is made to FIG. 9 and FIG. 10. FIG. 9 and FIG. 10 are partial cross-sectional views at different intermediate stages of the manufacturing method at another view angle according to an embodiment of the present disclosure. In detail, FIG. 9 and FIG. 10 are cross-sectional views of the contact of the source region 130. The process stage in FIG. 9 corresponds to the process stage in FIG. 3. As shown in FIG. 9, a trench 112 may be first formed in a semiconductor substrate 110 by an etching process. Later on, a first insulating layer 120 may be formed in the trench 112 and on a top surface 114 of the semiconductor substrate 110. For example, oxide may be used to form the first insulating layer 120. However, it is not limited thereto. After forming the first insulating layer 120, a source region 130 may be formed in the first insulating layer 120. In this embodiment, polysilicon is used to form the source region 130 in the first insulating layer 120.

The process stage in FIG. 10 corresponds to the process stage in FIG. 5. As shown in FIG. 10, a second insulating layer 140 is formed on the first insulating layer 120 by wet oxidation. A part of the source region 130 is converted to the second insulating layer 140. In detail, in the wet oxidation process, the source region 130 including polysilicon can be partially converted to the second insulating layer 140. Moreover, a ratio of a formation rate of the second insulating layer 140 on the source region 130 including polysilicon to a formation rate of the second insulating layer 140 on the first insulating layer 120 is about 3:1.

Referring back to FIG. 1B, a third insulating layer 160 may be formed on the second insulating layer 140. Next, after the third insulating layer 160 is formed, a metal contact 170 can be formed on the third insulating layer 160. The metal contact 170 extends into the semiconductor substrate 110 to contact the source region 130, which forms the structure shown in FIG. 1B.

According to the foregoing recitations of the embodiments of the disclosure, it may be seen that in the semiconductor structure and the manufacturing method of the semiconductor structure of the present disclosure, by disposing the two gate regions of the semiconductor structure in the second insulating layer and separating the two gate regions by the second insulating layer, structural defects may be avoided when forming the gate regions. In addition, the two gate regions separated by the second insulating layer and disposed symmetrically can enhance the electrical characteristics of the semiconductor structure. Therefore, the device reliability of the gate regions of the semiconductor structure and the performance of the semiconductor structure may be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor structure, comprising:
a first insulating layer disposed in a trench of a semiconductor substrate;
a source region disposed in the first insulating layer, wherein the source region has a first portion and a second portion extending from the first portion, and the first insulating layer surrounds the first portion of the source region;
a second insulating layer disposed on the first insulating layer and extending to a top surface of the semiconductor substrate, wherein the second insulating layer covers the second portion of the source region; and
two gate regions disposed in the second insulating layer, wherein the two gate regions are separated by the second insulating layer.

2. The semiconductor structure of claim 1, wherein the two gate regions are disposed symmetrically along a longitudinal direction of the trench.

3. The semiconductor structure of claim 1, wherein a length of the first portion of the source region is greater than a length of one of the two gate regions.

4. The semiconductor structure of claim 1, wherein the semiconductor substrate has an implantation region, and a position of the implantation region corresponds to a position of one of the two gate regions.

5. The semiconductor structure of claim 4, further comprising:
a metal contact extending into the semiconductor substrate to contact the implantation region of the semiconductor substrate; and
a third insulating layer disposed between the second insulating layer and the metal contact.

6. The semiconductor structure of claim 5, wherein the metal contact is in contact with the source region.

7. The semiconductor structure of claim 5, wherein the third insulating layer covers the two gate regions.

8. The semiconductor structure of claim 1, wherein the source region comprises polysilicon.

9. A manufacturing method of a semiconductor structure, comprising:
forming a first insulating layer in a trench of a semiconductor substrate;
forming a source region in the first insulating layer, wherein the source region has a first portion and a second portion extending from the first portion;
etching the first insulating layer by wet etching to expose the second portion of the source region;
forming a second insulating layer on the first insulating layer by wet oxidation, wherein a part of the second portion of the source region is converted to the second insulating layer; and
forming two gate regions in the second insulating layer, wherein the two gate regions are separated by the second insulating layer.

10. The manufacturing method of claim 9, wherein the two gate regions are disposed symmetrically along a longitudinal direction of the trench.

11. The manufacturing method of claim 9, wherein a length of the first portion of the source region is greater than a length of one of the two gate regions.

12. The manufacturing method of claim 9, wherein polysilicon is used to form the source region in the first insulating layer.

13. The manufacturing method of claim 9, further comprising:
implanting a top surface of the semiconductor substrate such that the semiconductor substrate has an implantation region, wherein a position of the implantation region corresponds to a position of one of the two gate regions.

14. The manufacturing method of claim 13, further comprising:
forming a third insulating layer on the second insulating layer, wherein the third insulating layer covers the two gate regions; and
forming a metal contact on the third insulating layer, wherein the metal contact extends into the semiconductor substrate to contact the implantation region of the semiconductor substrate.

15. The manufacturing method of claim 14, wherein the metal contact is in contact with the source region.
